(19) United States
(12) Patent Application Publication
(10) Pub. No.: US 2026/0025125 A1
(43) Pub. Date: Jan. 22, 2026

(54) ACTIVE UNBALANCED-TO-BALANCED CONVERTER CIRCUIT

(71) Applicant: Skyworks Solutions, Inc., Irvine, CA (US)

(72) Inventor: John Jackson Nisbet, Ottawa (CA)

(21) Appl. No.: 19/268,601

(22) Filed: Jul. 14, 2025

Related U.S. Application Data
(60) Provisional application No. 63/671,928, filed on Jul. 16, 2024.

(51) Int. Cl. H03H 11/32; H03F 3/24; H04B 1/04

(52) U.S. Cl. CPC H03H 11/32; H03F 3/245; H04B 1/04; H03F 2200/451; H04B 2001/0408

(57) ABSTRACT

An active unbalanced-to-balanced converter circuit converts a single-ended radio frequency input signal to a pair of differential signals. The converter circuit includes a current mirror circuit coupled to the input signal and having a first transistor and a second transistor. The converter circuit also has as differential amplifier with a third transistor coupled between the first transistor and the first output and being configured to provide a first amplified output signal, and with a fourth transistor coupled between the second transistor and the second output and being configured to provide a second amplified output signal. A bias circuit is coupled to the third transistor and the fourth transistor to provide a bias voltage to the differential amplifier.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the disclosure relate to an active unbalanced-to-balanced converter circuit. Embodiments of the disclosure also relate to a power amplifier module, and a wireless device.

### Description of the Related Technology

In some RF applications it can be advantageous to use differential signals. For example, on-chip differential signals can provide intrinsic even harmonic suppression and allow more optimal impedance scaling. On the other hand, signals off-chip are typically single-ended with a given characteristic impedance, for example 50 ohms. Therefore, to use on-chip differential circuits effectively, the signals require conversion between the balanced single-ended signals off-chip and the unbalanced differential signals on-chip.

For example, FIG. 1 illustrates an example of a power amplifier circuit according to the prior art. In the arrangement of FIG. 1, power amplifiers 101 and 103 are implemented on an integrated circuit die 105. The circuit comprises an unbalanced-to-balanced converter circuit 107 (herein referred to as an unbal) implemented off-chip (not on the integrated circuit die 105), and a balanced-to-unbalanced converter circuit 109 (herein referred to as a balun) also implemented off-chip. The unbal 107 and balun 109 may be designed as part of the integrated circuit package, or may be provided as separate components inside the package or outside of the package. An input signal 111 provided to the unbal 107 and output signal 113 provided by the balun 109 may be single-ended signals having a characteristic impedance of 50 ohms. On-chip signals 115 are differential signals having characteristic impedances.

Conventionally, unbals and baluns are implemented as passive elements and can be provided through several arrangements, each having its own drawbacks. There is therefore a need for an improved unbal converter.

### SUMMARY

In some aspects, the techniques described herein relate to an active unbalanced-to-balanced converter circuit including: a first output and a second output configured to output a pair of differential signals corresponding to a single-ended radio frequency input signal; a current mirror circuit coupled to the input signal and including a first transistor and a second transistor; a differential amplifier including a third transistor and a fourth transistor, the third transistor coupled between the first transistor and the first output and being configured to provide a first amplified output signal to the first output, and the fourth transistor coupled between the second transistor and the second output and being configured to provide a second amplified output signal to the second output; and a bias circuit coupled to the third transistor and the fourth transistor and being configured to provide a bias voltage to the differential amplifier.

In some aspects, the techniques described herein relate to an active unbalanced-to-balanced converter circuit further including: a first capacitor coupled between the third transistor and the fourth transistor; a second capacitor coupled between the third transistor and a common ground, the second capacitor being configured to control an impedance at the third transistor; and a third capacitor coupled between the fourth transistor and the common ground, the third capacitor being configured to control an impedance at the fourth transistor.

In some aspects, the techniques described herein relate to an active unbalanced-to-balanced converter circuit wherein a capacitance of the first capacitor is relatively large compared to the capacitance of the second capacitor and the third capacitor.

In some aspects, the techniques described herein relate to an active unbalanced-to-balanced converter circuit wherein the second capacitor is configured to control an impedance at an emitter of the third transistor, and the third capacitor is configured to control an impedance at an emitter of the fourth transistor.

In some aspects, the techniques described herein relate to an active unbalanced-to-balanced converter circuit wherein a capacitance of the second capacitor and the third capacitor are adjustable.

In some aspects, the techniques described herein relate to an active unbalanced-to-balanced converter circuit further including a first resistor coupled between an input of the active unbalanced-to-balanced converter circuit and the first transistor, and the input and the third transistor, the first resistor being configured to set an input impedance.

In some aspects, the techniques described herein relate to an active unbalanced-to-balanced converter circuit further including a first inductor coupled between the third transistor and the first output, and a second inductor coupled between the fourth transistor and the second output, the first inductor and the second inductor being coupled in symmetrical anti-phase.

In some aspects, the techniques described herein relate to an active unbalanced-to-balanced converter circuit further including a fourth capacitor and fifth capacitor coupled between the third transistor and the first output, and a sixth capacitor and a seventh capacitor coupled between the fourth transistor and the second output, the fourth and fifth capacitors being configured to provide impedance matching to the first amplified output signal and to block direct current at the first output, the sixth and seventh capacitors being configured to provide impedance matching to the second amplified output signal and to block direct current at the second output.

In some aspects, the techniques described herein relate to an active unbalanced-to-balanced converter circuit wherein the fourth, fifth, sixth, and seventh capacitors are tapped-capacitor impedance transformers.

In some aspects, the techniques described herein relate to an active unbalanced-to-balanced converter circuit further including a capacitor coupled to an input of the active unbalanced-to-balanced converter circuit and being configured to provide direct current blocking and a third inductor coupled between the input and the third transistor.

In some aspects, the techniques described herein relate to an active unbalanced-to-balanced converter circuit wherein the second amplified output signal has a phase difference of 180 degrees from the first amplified output signal.

In some aspects, the techniques described herein relate to an active unbalanced-to-balanced converter circuit wherein the bias circuit is coupled to the differential amplifier via a pair of resistors.

In some aspects, the techniques described herein relate to an active unbalanced-to-balanced converter circuit wherein the differential amplifier is a common-base amplifier, an emitter of the third transistor is coupled to a collector of the first transistor, a base of the third transistor is coupled to the bias circuit, and a collector of the third transistor is coupled to the first output.

In some aspects, the techniques described herein relate to an active unbalanced-to-balanced converter circuit wherein an emitter of the fourth transistor is coupled to a collector of the second transistor, a base of the fourth transistor is coupled to the bias circuit, and a collector of the fourth transistor is coupled to the second output.

The active unbalanced-to-balanced converter circuit of claim 1 wherein the differential amplifier is a common-gate amplifier, a source of the third transistor is coupled to a drain of the first transistor, a gate of the third transistor is coupled to the bias circuit, and a drain of the third transistor is coupled to the first output.

The active unbalanced-to-balanced converter circuit of claim 15 wherein a source of the fourth transistor is coupled to a drain of the second transistor, a gate of the fourth transistor is coupled to the bias circuit, and a drain of the fourth transistor is coupled to the second output.

In some aspects, the techniques described herein relate to an active unbalanced-to-balanced converter circuit wherein the bias circuit is coupled to the first transistor and the second transistor and is configured to provide the bias voltage to the current mirror circuit.

In some aspects, the techniques described herein relate to an active unbalanced-to-balanced converter circuit wherein the first transistor, second transistor, third transistor, and fourth transistor are N-channel transistors.

In some aspects, the techniques described herein relate to an active unbalanced-to-balanced converter circuit wherein the bias circuit includes a reference current, the bias circuit being configured to increase the reference current by a factor of N where N is a ratio of an operating current of the first transistor and the second transistor compared with the reference current in the bias circuit.

In some aspects, the techniques described herein relate to a radio frequency module including: an active unbalanced-to-balanced converter circuit including: a first output and a second output configured to output a pair of differential signals corresponding to a single-ended radio frequency input signal; a current mirror circuit coupled to an input signal and including a first transistor and a second transistor; a differential amplifier including a third transistor and a fourth transistor, the third transistor coupled between the first transistor and the first output and being configured to provide a first amplified output signal to the first output, and the fourth transistor coupled between the second transistor and the second output and being configured to provide a second amplified output signal to the second output; and a bias circuit coupled to the third transistor and the fourth transistor and being configured to provide a bias voltage to the differential amplifier; and one or more power amplifiers coupled to the active unbalanced-to-balanced converter circuit.

In some aspects, the techniques described herein relate to a radio frequency module wherein the differential amplifier is a common-base amplifier, an emitter of the third transistor is coupled to a collector of the first transistor, a base of the third transistor is coupled to the bias circuit, and a collector of the third transistor is coupled to the first output

In some aspects, the techniques described herein relate to a wireless communication device including a radio frequency module implemented on a die, the radio frequency module including: an active unbalanced-to-balanced converter circuit including: a first output and a second output configured to output a pair of differential signals corresponding to a single-ended radio frequency input signal; a current mirror circuit coupled to the input signal and including a first transistor and a second transistor; a differential amplifier including a third transistor and a fourth transistor, the third transistor coupled between the first transistor and the first output and being configured to provide a first amplified output signal to the first output, and the fourth transistor coupled between the second transistor and the second output and being configured to provide a second amplified output signal to the second output; a bias circuit coupled to the third transistor and the fourth transistor and being configured to provide a bias voltage to the differential amplifier; one or more power amplifiers coupled to the active unbalanced-to-balanced converter circuit; and one or more radio frequency antennas.

According to one embodiment, there is provided an active unbalanced-to-balanced converter circuit comprising: an input configured to receive an input signal; a first output and a second output configured to output a pair of differential signals corresponding to the input signal; a current mirror circuit coupled to the input and including a first transistor and a second transistor; a differential common-base amplifier including a third transistor and a fourth transistor, the third transistor coupled between the first transistor and the first output and being configured to provide a first amplified output signal to the first output, and a fourth transistor coupled between the second transistor and the second output and being configured to provide a second amplified output signal to the second output; a bias circuit coupled to the third transistor and the fourth transistor and being configured to provide a bias voltage to the differential common-base amplifier; a first capacitor coupled between the third transistor and fourth transistor; a second capacitor coupled between the third transistor and a common ground, the second capacitor being configured to control an impedance at the third transistor; and a third capacitor coupled between the fourth transistor and the common ground, the third capacitor being configured to control an impedance at the fourth transistor.

In one example, the input signal is a single-ended radio frequency input signal.

In one example, the second capacitor is configured to control an impedance at an emitter of the third transistor, and the third capacitor is configured to control an impedance at an emitter of the fourth transistor.

In one example, the active unbalanced-to-balanced converter circuit further comprises a first resistor coupled between the input and the first transistor, the first resistor being configured to set an input impedance.

In one example, the active unbalanced-to-balanced converter circuit further comprises a first inductor coupled between the third transistor and the first output, and a second inductor coupled between the fourth transistor and the second output.

In one example, the first and second inductors are coupled in symmetrical anti-phase.

In one example, the active unbalanced-to-balanced converter circuit further comprises a fourth capacitor and fifth capacitor coupled between the third transistor and the first differential output, and a sixth capacitor and a seventh capacitor coupled between the fourth transistor and the second differential output, the fourth and fifth capacitors being configured to provide impedance matching to the first amplified output signal and to block direct current at the first output, the sixth and seventh capacitors being configured to provide impedance matching to the second amplified output signal and to block direct current at the second output.

In one example, the fourth, fifth, sixth, and seventh capacitors are tapped-capacitor impedance transformers.

In one example, the active unbalanced-to-balanced converter circuit further comprises a capacitor coupled to the input and being configured to provide direct current blocking.

In one example, the active unbalanced-to-balanced converter circuit further comprises a third inductor coupled between the input and the third transistor.

In one example, a capacitance of the second capacitor and the third capacitor are adjustable.

In one example, the second amplified output signal has a phase difference of 180 degrees from the first amplified output signal.

In one example, the bias circuit is coupled to the differential common-base amplified via a pair of resistors.

In one example, an emitter of the third transistor is coupled to a collector of the first transistor, a base of the third transistor is coupled to the bias circuit, and a collector of the third transistor is coupled to the first output.

In one example, an emitter of the fourth transistor is coupled to a collector of the second transistor, a base of the fourth transistor is coupled to the bias circuit, and a collector of the fourth transistor is coupled to the second output.

In one example, the bias circuit is coupled to the first transistor and the second transistor and is configured to provide a current mirror bias voltage to the current mirror circuit.

In one example, the first transistor, second transistor, third transistor, and fourth transistor are N-channel transistors.

In one example, the bias circuit includes a reference current, the bias circuit being configured to increase the reference current by a factor of N where N is a ratio of an operating current of the first transistor and the second transistor compared with the reference current in the bias circuit.

According to another embodiment, there is provided a radio frequency module implemented on a die, the radio frequency module comprising: an active unbalanced-to-balanced converter circuit including: an input configured to receive an input signal; a first output and a second output configured to output a pair of differential signals corresponding to the input signal; a current mirror circuit coupled to the input and including a first transistor and a second transistor; a differential common-base amplifier including a third transistor and a fourth transistor, the third transistor coupled between the first transistor and the first output and being configured to provide a first amplified output signal to the first output, and a fourth transistor coupled between the second transistor and the second output and being configured to provide a second amplified output signal to the second output; a bias circuit coupled to the third transistor and the fourth transistor and being configured to provide a bias voltage to the differential common-base amplifier; a first capacitor coupled between the third transistor and fourth transistor; a second capacitor coupled between the third transistor and a common ground, the second capacitor being configured to control an impedance at the third transistor; and a third capacitor coupled between the fourth transistor and the common ground, the third capacitor being configured to control an impedance at the fourth transistor, and one or more power amplifiers coupled to the active unbal circuit.

According to another embodiment, there is provided a wireless communication device comprising a radio frequency module implemented on a die, the radio frequency module including: an active unbalanced-to-balanced converter circuit including: an input configured to receive an input signal; a first output and a second output configured to output a pair of differential signals corresponding to the input signal; a current mirror circuit coupled to the input and including a first transistor and a second transistor; a differential common-base amplifier including a third transistor and a fourth transistor, the third transistor coupled between the first transistor and the first output and being configured to provide a first amplified output signal to the first output, and a fourth transistor coupled between the second transistor and the second output and being configured to provide a second amplified output signal to the second output; a bias circuit coupled to the third transistor and the fourth transistor and being configured to provide a bias voltage to the differential common-base amplifier; a first capacitor coupled between the third transistor and fourth transistor; a second capacitor coupled between the third transistor and a common ground, the second capacitor being configured to control an impedance at the third transistor; and a third capacitor coupled between the fourth transistor and the common ground, the third capacitor being configured to control an impedance at the fourth transistor, and one or more power amplifiers coupled to the active unbal circuit.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the disclosure. In the figures, each identical or nearly identical component that is illustrated in various figures is represented by a like numeral. For purposes of clarity, not every component may be labeled in every figure. In the figures:

FIG. 1 is a schematic diagram of a power amplifier circuit according to the prior art;

FIG. 2A is a circuit diagram of an unbalanced-to-balanced converter circuit according to the prior art;

FIG. 2B is a circuit diagram of an unbalanced-to-balanced converter circuit according to the prior art;

FIG. 2C is a circuit diagram of an unbalanced-to-balanced converter circuit according to the prior art;

FIG. 2D is a circuit diagram of an unbalanced-to-balanced converter circuit according to the prior art;

FIGS. 3A-3C are schematic diagrams of power amplifier circuits according to aspects of the present disclosure;

FIGS. 4A-4B are circuit diagrams of an unbalanced-to-balanced converter circuit according to aspects of present disclosure;

FIG. 5 is a circuit diagram of a bias circuit for providing a bias voltage to an unbalanced-to-balanced converter circuit according to aspects of the present disclosure;

FIG. 6 is a schematic block diagram of a module including an unbalanced-to-balanced converter according to aspects of the present disclosure;

FIG. 7 is a schematic block diagram of a module including an unbalanced-to-balanced converter circuit according to aspects of the present disclosure;

FIG. 8 is a schematic block diagram of a module including an unbalanced-to-balanced converter circuit according to aspects of the present disclosure; and

FIG. 9 is a schematic diagram of a wireless device including an unbalanced-to-balanced converter circuit according to aspects of the present disclosure.

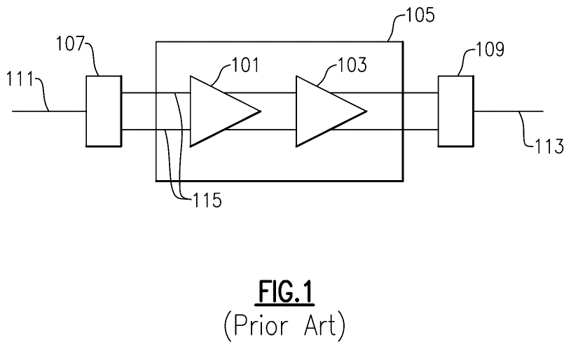

### DETAILED DESCRIPTION

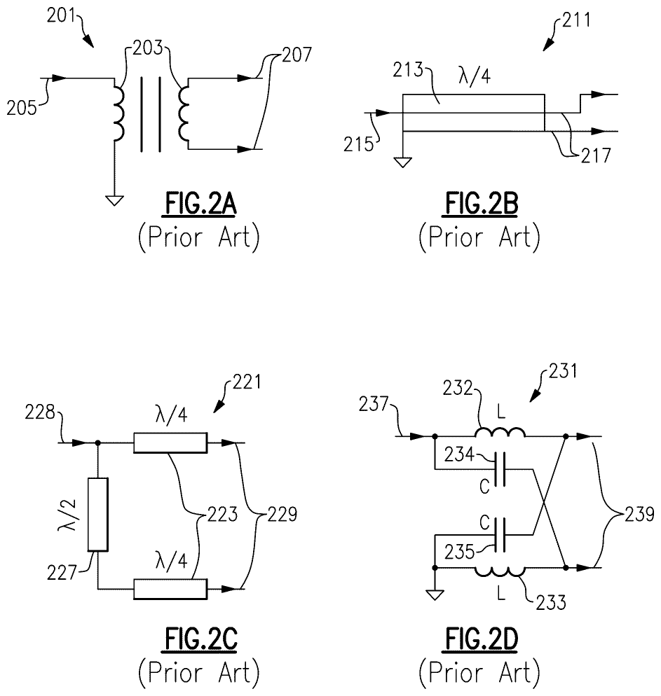

Aspects and embodiments described herein are directed to an active unbalanced-to-balanced (unbal) converter circuit for converting an unbalanced single-ended input signal to a pair of balanced differential signals. The unbal converter circuit according to arrangements described herein advantageously provides good amplitude and phase balance over a wide bandwidth, and preferably over more than an octave. In addition, the inventor of the present disclosure has appreciated that the design of the active unbal converter circuit may be compact, resulting in a lower die or package area cost when compared to existing unbal circuits (discussed in more detail below with respect to FIGS. 2A to 2D), allowing the circuit to be implemented on-chip.

Embodiments of the present disclosure will be described with reference to the accompanying Figures. In addition, embodiments of the active unbal converter circuit according to aspects of the present disclosure will initially be described by comparison with existing unbal converter circuits. Example existing unbal converter circuits according to the prior art are illustrated in FIGS. 2A to 2D. These examples are used by way of comparison only, in order to better describe and highlight advantages of the present disclosure, and is not intended to limit the scope of the present disclosure.

FIG. 2A illustrates a first example of an existing unbal converter circuit 201 design according to the prior art. The unbal converter circuit 201 comprises two magnetically coupled inductors 203 (forming a transformer) configured to transfer energy from an unbalanced circuit received at an input 205 to a balanced circuit through outputs 207. Such an arrangement may provide operability over a wide bandwidth, low loss, and good balancing properties. However, the inventor of the present disclosure has appreciated that the transformer winding inductive reactance must be large compared to the impedances being transformed. This leads to a physically large transformer, particularly at low frequencies, which is costly in die or package area. In addition, performance of the unbal circuit may be impaired by parasitic capacitance.

FIG. 2B illustrates a second example of an existing unbal converter circuit 211 design according to the prior art. The unbal converter circuit 211 comprises a quarter-wave section of a coaxial line 213 having a length

$$L = \frac{λ}{4}$$

which is unbalanced at a first end 215 and balanced at a second end 217 where A is the wavelength of an input signal input at the first end 215. The inventor of the present disclosure has appreciated that this arrangement is difficult to implement in planar technology and is physically large at low frequencies. It is also intrinsically band limited. FIG. 2C similarly illustrates a third example of an existing unbal converter circuit 221 design according to the prior art, which is also implemented using transmission lines 223, having a length

$$L = \frac{λ}{4}$$

and transmission line 227 having a length

$$L = \frac{λ}{2} .$$

An unbalanced input signal is received at input 228 and balanced outputs are provided at outputs 229. However, while this arrangement is easier to implement in planar technology, it is even larger and is also similarly intrinsically band limited.

FIG. 2D illustrates a fourth example of an existing unbal converter circuit 231 design according to the prior art. In this existing example, the unbal converter circuit 231 is implemented as a lumped LC unbal, having a first inductor 232, a second inductor 233, a first capacitor 234, and a second capacitor 235. An unbalanced input signal is received at input 237 and balanced outputs are provided at outputs 239. This arrangement may have low loss and may be convenient to implement using surface-mount components inside or outside of an IC package, or on-chip. However, the inventor of the present disclosure has appreciated that this arrangement has poor amplitude balance away from a center frequency and is even more band-limited than the implementations described with respect to FIGS. 2B and 2C.

Thus, the inventor of the present disclosure has appreciated that an improved unbal circuit may be provided as an active unbal circuit providing good amplitude and phase balance over a wide bandwidth, preferably more than an octave. Such an improved unbal circuit according to embodiments described herein is compact and conveniently suitable for implementation on-chip, and provides excellent matching on all ports.

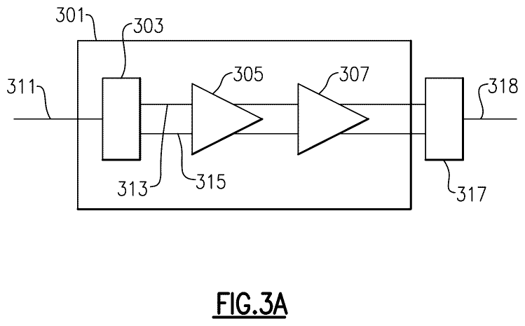

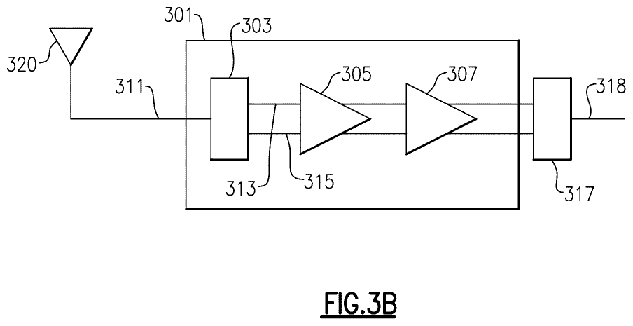

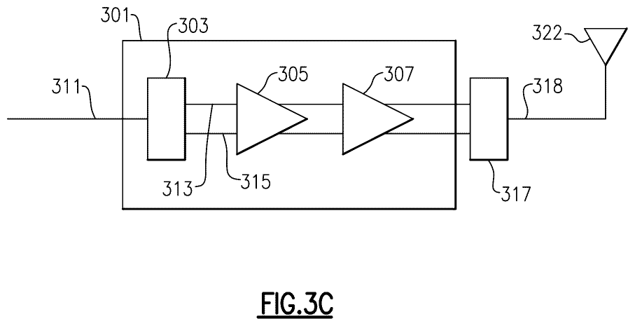

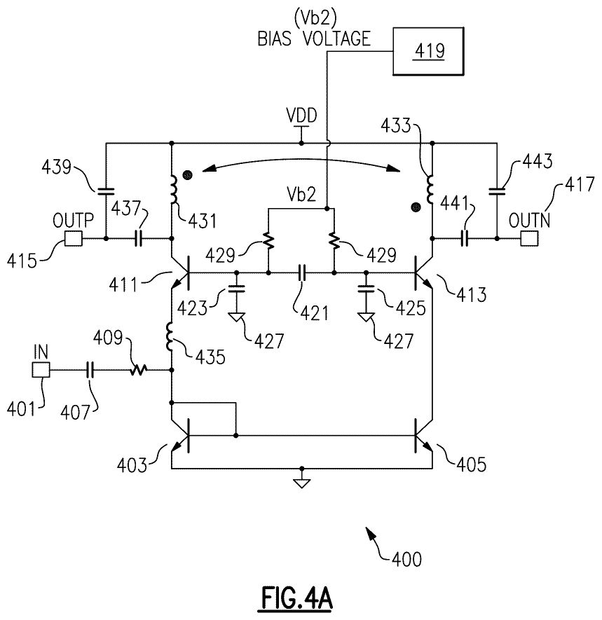

FIG. 3A illustrates an example power amplifier circuit according to some embodiments. The power amplifier circuit is arranged at least partially on an integrated circuit die 301. Conveniently, due to the design of the active unbal converter circuit according to embodiments described herein, an unbal converter circuit 303 is implemented on-chip, together with power amplifiers 305, 307. In this example, the integrated circuit die 301 comprises the unbal converter circuit 303 and power amplifiers 305, 307. However, it will be appreciated that the integrated circuit die 301 could include one or more additional components or fewer amplifiers (for example, one amplifier).

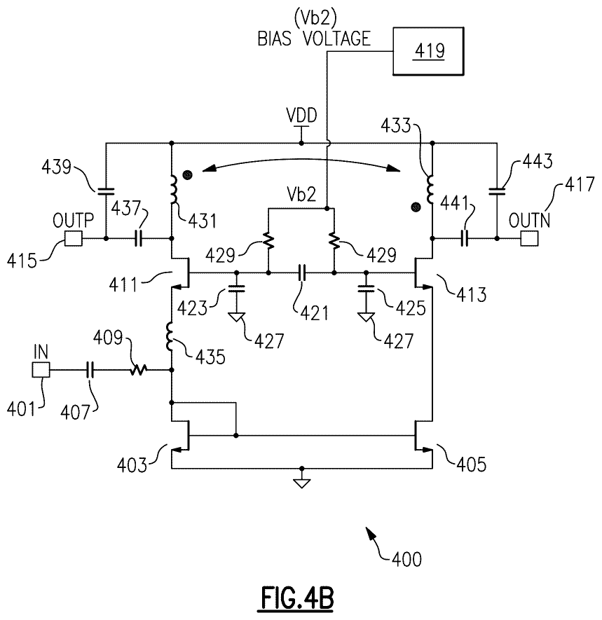

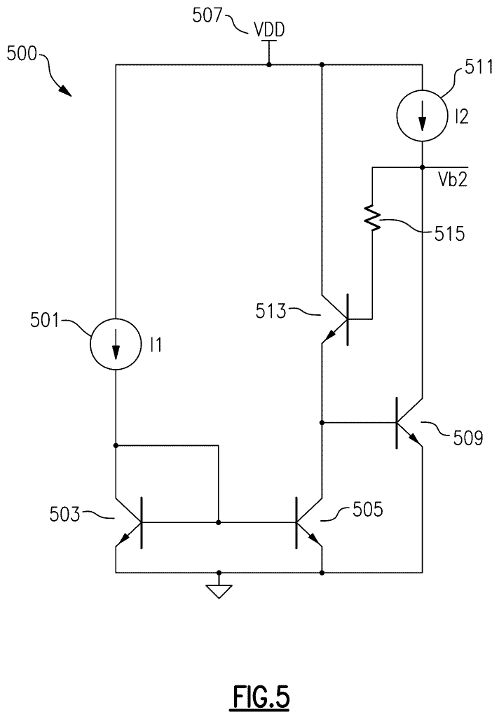

The active unbal converter circuit 303 receives, at an input 311, an unbalanced single-ended input signal, which in this example is a radio frequency input signal. The active unbal converter circuit 303 converts the unbalanced input signal to a pair of differential output signals 313, 315 (described in more detail with respect to FIGS. 4 and 5 below) and provides the differential output signals 313, 315 to the power amplifiers 305, 307 on the integrated circuit die 301. The differential signals 313 and 315 output by the amplifier 307 are provided to a balanced-to-unbalanced (balun) converter circuit 317 configured to convert the differential output signals 313, 315 into an unbalanced single-ended signal. In this example, the balun 317 is implemented off-chip. A balun 317 is arranged off-chip and is configured to received the differential signals from the on-chip amplifier 307. The balun 317 converts the balanced differential signals output from the amplifier 307 to a single-ended signal and provides the unbalanced single-ended signal to the output 318.

FIG. 3B illustrates that the single ended input signal 311 can be driven by an antenna 320. In such an embodiment, the amplifiers 305, 307 can be low noise amplifiers in a receive path of a radio frequency front end. FIG. 3C illustrates that the output 318 can drive an antenna 322. In such an embodiment, the amplifiers 305, 307 can be power amplifiers in a transmit path of a radio frequency front end.

FIG. 4A illustrates the active unbal converter circuit 400 according to some embodiments. The unbal circuit 400 comprises an input 401 configured to receive an input signal, which in this example is a single-ended input signal which may be a radio frequency signal. The input 401 is coupled to a current mirror circuit which includes a first transistor 403 and a second transistor 405. The input 401 is coupled to a collector of the first transistor 403.

In this example, the input 401 is coupled to the first transistor 403 via a capacitor 407 configured to provide direct current blocking. The impedances at the collector of the first transistor 403 and at the emitter of the third transistor 411 are ideally low, for example close to a wideband short circuit. Therefore, the input 401 is also coupled to the first transistor 403 and the third transistor 411 via a first resistor 409 configured to set an input impedance to the active unbal circuit. In some examples, the first resistor 409 may have a resistance value approximately equal to an impedance of the input signal. The first resistor 409 advantageously provides good input matching over a wide bandwidth. In addition, the first resistor 409 implemented in the described active circuit provides a flat, excellent wide band return loss.

The active unbal circuit 400 also comprises a differential common-base amplifier including a third transistor 411 and a fourth transistor 413. Broadly, the active unbal circuit 400 includes a differential common-base amplifier stacked on top of a current mirror circuit, providing exceptional operational bandwidth intrinsically provided by the common-base amplifier on top of the current mirror as both the common-base amplifier and the current mirror circuit provide may operate over a wide bandwidth.

More specifically, the active unbal circuit 400 comprises a first output 415 and a second output 417 configured to output a pair of differential signals corresponding to the input signal. The third transistor 411 is coupled between the first transistor 403 and the first output 415, and the third transistor 411 is configured to provide a first amplified output signal to the first output. The fourth transistor 413 is coupled between the second transistor 405 and the second output 417, and the fourth transistor is configured to provide a second amplified output signal to the second output 417. Implementing the common-base amplifier including the third transistor 411 and the fourth transistor 413 coupled to the current mirror circuit including the first transistor 403 and the second transistor 405 advantageously provides a high isolation from output to input, which cannot be achieved by a passive unbal arrangement.

The active unbal circuit 400 also comprises a bias circuit 419 coupled to the third transistor 411 and the fourth transistor 413. The bias circuit 419 is configured to provide a bias voltage Vb2 to the differential common-base amplifier. In this example, an emitter of the third transistor 411 is coupled to a collector of the first transistor 403, a base of the third transistor 411 is coupled to the bias circuit 419, and a collector of the third transistor 411 is coupled to the first output 415. An emitter of the fourth transistor 413 is coupled to a collector of the second transistor 405, a base of the fourth transistor 413 is coupled to the bias circuit 419, and a collector of the fourth transistor 413 is coupled to the second output 417.

In this example, the bias circuit 419 also provides a bias voltage to the current mirror circuit, the bias circuit 419 being coupled to collectors of the first transistor 403 and the second transistor 405. For example, the bias circuit 419 is coupled to the collector of the first transistor 403 via a path including the left resistor of the pair of resistors 429, the base-emitter junction of the third transistor 411, and the inductor 435. The bias circuit 419 is coupled to the collector of the second transistor 405 via a path including the right resistor of the pair of resistors 429 and the base-emitter junction of the fourth transistor 413. An example bias circuit is described in more detail below with respect to FIG. 5.

The active unbal circuit 400 comprises a first capacitor 421 coupled between the third transistor 411 and the fourth transistor 413. The first capacitor 421 is also coupled to the bias circuit 419. The active unbal circuit 400 further includes a second capacitor 423 coupled between a base of the third transistor 411 and a common ground 427. The second capacitor 423 is configured to control an impedance at an emitter of the third transistor 411. The active unbal circuit 400 further includes a third capacitor 425 coupled between a base of the fourth transistor 413 and the common ground 427. The third capacitor 425 is configured to control an impedance at an emitter base of the fourth transistor 413. Some or all of the first, second, and third capacitors 421, 423, 425 can be adjustable capacitors.

In this example, the capacitance of the first capacitor 421 is relatively large compared to the capacitance of the second capacitor 423 and the third capacitor 425. For example, the capacitance of the first capacitor 421 may be at least five times as large as the capacitance of the second capacitor 423 and the third capacitor 425. This advantageously provides high differential-mode gain and low common-mode gain which are both highly desirable. In addition, the second capacitor 423 and the third capacitor 425 also provide amplitude and phase balancing.

Preferably, the capacitance of the second capacitor 423 and the third capacitor 425 are equal. However, in practice, this may not be possible. Therefore, in this example, the capacitance of the second capacitor 423 and the capacitance third capacitor 425 are adjustable. For example, it will be understood by the skilled person that a value of a capacitor may be adjusted to a common ground. Small adjustments in the capacitance of the second capacitor 423 and the third capacitor 425 relative to each other may therefore be made. This provides the ability to tune or adjust the phase and amplitude of the pair of amplified differential output signals provided by the differential common-base amplifier to exactly balance equal amplitude of the signals at the first output 415 and the second output 417, while providing the pair of output signals with a 180 degree phase difference. This may be over a sub-section of an operating bandwidth of the active unbal circuit 400. For example, a good amplitude and phase balance of the pair of differential output signals may be provided over a wide bandwidth, but one or more sub-bands for which a high accuracy is desired may be adjustable to account, for example, for process variation and to provide the desired accuracy across the one or more sub-bands.

The bias circuit 419 is coupled to the differential common-base amplifier via a pair of resistors 429. The resistors 429 have a relatively high resistance such that perturbation from radio frequency signals may be prevented. The size of the resistors 429 are described in more detail with respect to the bias circuit described at FIG. 5.

The active unbal circuit 400 includes a first inductor 431 coupled between a collector of the third transistor 411 and a common power supply VDD, and a second inductor 433 coupled between a collector of the fourth transistor 413 and the common power supply VDD. The differential output signals output from the third transistor 411 and the fourth transistor 413 of the differential common-base amplifier are provided to the first inductor 431 and the second inductor 433 respectively. In this example, the first and second inductors are coupled in symmetrical anti-phase which further improves common-mode rejection. This also reduces the area cost of the components when compared with non-coupled inductors. However, it will be appreciated that non-coupled inductors may be used.

The input may also be coupled to the third transistor 411 via a third inductor 435. The third inductor is configurable to allow for additional phase and amplitude balance of the pair of differential output signals.

As described, the input 401 is direct current blocked by capacitor 407, configured to block direct current present at the collector of the first transistor 403 resulting from the active circuit stacked on top of the current mirror circuit. Similarly to the input 401, the first output 415 and second output 417 are direct current (DC) blocked to prevent DC conditions being imposed before of after the active unbal circuit 400. The active unbal circuit 400 comprises a fourth capacitor 437 and fifth capacitor 439 coupled between the third transistor 411 and the first differential output 415, and a sixth capacitor 441 and a seventh capacitor 443 coupled between the fourth transistor 413 and the second differential output 417. The fourth capacitor 437 and fifth capacitor 439 are configured to provide impedance matching to the first amplified output signal and to block direct current at the first output 415. The sixth capacitor 441 and seventh capacitor 443 are configured to provide impedance matching to the second amplified output signal and to block direct current at the second output 417. In some examples, the fourth, fifth, sixth, and seventh capacitors are tapped-capacitor impedance transformers configured to match the outputs to a desired load impedance.

Each of the first to fourth transistors may be N-channel transistors or devices (NPN or NFET) in any bipolar junction (BJT) or metal-oxide-semiconductor (MOS) process. For example, FIG. 4B illustrates an embodiment that uses NFET transistors, where the third transistor 411 and the fourth transistor form a differential common-gate amplifier, and the input 401 is coupled to a drain of the first transistor 403. N-channel devices may be particular advantageous when compared to P-channel devices due to the superior high-frequency performance of N-channel devices. However, it will be appreciated that the described transistors may also be implemented as P-channel devices.

The arrangement of FIG. 4 therefore provides a differential common-base amplifier stacked on top of a current mirror circuit providing exceptional operational bandwidth intrinsically provided by the common base-amplifier on top of the current mirror circuit. Although the active unbal circuit 400 consumes DC power, it provides improved operating bandwidth, return losses, amplitude and phase balance, and reverse isolation (which the inventors have appreciated cannot be achieved by a passive unbal circuit). The input return loss can be excellent over several octaves of bandwidth because it is essentially resistively defined. The functional basis of the active unbal circuit 400 (an inverting current mirror loaded by a non-inverting common-base amplifier stage) has an intrinsic useful bandwidth from DC to about fT/10 where IT is the transition frequency.

FIG. 5 illustrates an example implementation of the bias circuit 419 of FIG. 4. It will be appreciated that the bias circuit 500 illustrates in FIG. 5 is particularly advantageous, but the described bias circuit is only an example. The bias circuit 500 is configured to provide a DC bias voltage Vb2 to the differential common-base amplifier, and in some examples, to the current mirror circuit. The bias circuit includes a reference current source 501 configured to reference current 11. The bias circuit 500 is configured to scale up the reference current 11 in the radio frequency devices of the active unbal converter circuit 400 (the first to fourth transistors). The bias circuit is configured to scale up the reference current 11 by a factor of N, where N is the ratio of an operating current in the first transistor and the second transistor compared with the reference current in the bias circuit.

The bias circuit comprises a current differencing amplifier including a fifth transistor 503 and a sixth transistor 505. The reference current source 501 is coupled between a positive supply voltage 507 and the fifth transistor 503 and the sixth transistor 505 of the current differencing amplifier. The current differencing amplifier also comprises a seventh transistor 509. A collector of the sixth transistor 505 is coupled to the base of the seventh transistor 509. Emitters of the fifth transistor 503 and sixth transistor 505 are coupled to a common ground, as well as being coupled to an emitter of the seventh transistor 509. The current differencing amplifier further comprises an active load source 511 configured to provide an active load current 12. The active load source 511 is coupled between the positive supply voltage 507 and a collector of the seventh transistor 509. The active load source 511 is also coupled to a base of an eighth transistor 513 via a resistor 515. A collector of the eighth transistor 513 is coupled to the positive supply voltage 507, and an emitter of the eighth transistor 513 is coupled to the collector of the sixth transistor 505 and the base of the seventh transistor 509.

The size of the sixth transistor 505 and the eighth transistor 513 may be set according to a size of the radio frequency devices (the first to fourth transistors) of the active unbal converter circuit 400. For example, the size of the sixth transistor 505 and the eighth transistor 513 may have a size 1:N where N is the ratio of an operating current in the first transistor and the second transistor (which may also be the operating current in the third transistor and the fourth transistor) compared with the reference current 11 in the bias circuit 500. The size of the resistor 515 may also be scaled correspondingly with respect to resistors 429 of the active unbal circuit 400 coupling the bias circuit to the differential common-base amplifier.

The effect of the bias circuit is to provide a DC bias of N*11 (the reference current scaled up by N) in the first transistor 403 and the second transistor 405, as well as providing a DC bias at least very close to this value in the third transistor 411 and the fourth transistor 413. In the bias circuit, it is desirable to have as little power as possible. N may take the value of 10 to 20, for example 15. If the scaling factor N is too low, energy is wasted leading to inefficiency. If N is too large, the operation of the active unbal circuit will be inaccurate over process and temperature. In some examples, where transistors are implemented as FETs, N may be larger, for example up to 30.

FIG. 6 is a schematic block diagram of a module 600 that includes an active unbal converter circuit 601 implemented in accordance with one or more embodiments described herein and having one or more advantageous features described herein. The module 600 may be a power amplifier module which may be a radio frequency power amplifier module, and in this example further comprises a power amplifier 602, a switch 604, and filters 606. The module 600 can include a package that encloses the illustrated elements. The active unbal converter circuit 601, power amplifier 602, the switch 604, and the filters 606 can be disposed on a common packaging substrate. The power amplifier 602 can amplify a radio frequency signal. The switch can be a multi-throw radio-frequency switch. The switch 604 can electrically couple an output of the power amplifier 602 to a selected filter of the filters 606. The filters 606 may include any number of filters.

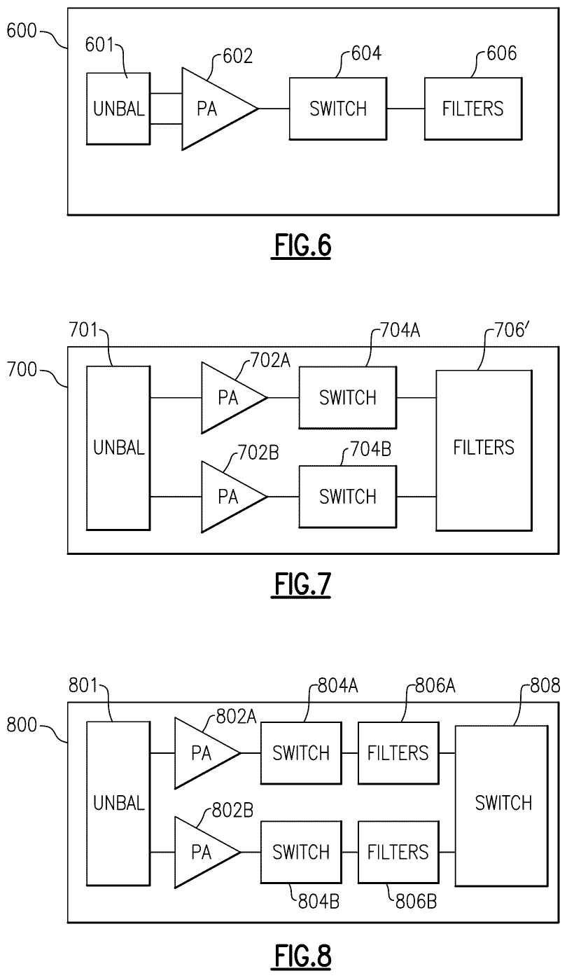

FIG. 7 is a schematic block diagram of a module 700 that includes an active unbal converter circuit 701 implemented in accordance with one or more embodiments described herein and having one or more advantageous features described herein. The active unbal converter circuit 701 may be implemented as a single circuit or one or more separate converter circuits arranged to convert signals for the signal paths associated with a plurality of power amplifiers 702A and 702B. The module 700 also includes power amplifiers 702A and 702B, switches 704A and 704B, and filters 706′. The module 700 is like the module 600 of FIG. 6 except that the module 700 includes an additional power amplifier 702B and an additional switch 704B and the filters 706′ are arranged to filter signals for the signal paths associated with a plurality of power amplifiers 702A and 702B. The different signal paths may be associated with different frequency bands and/or different modes of operation (e.g. different power modes, different signalling modes, etc.).

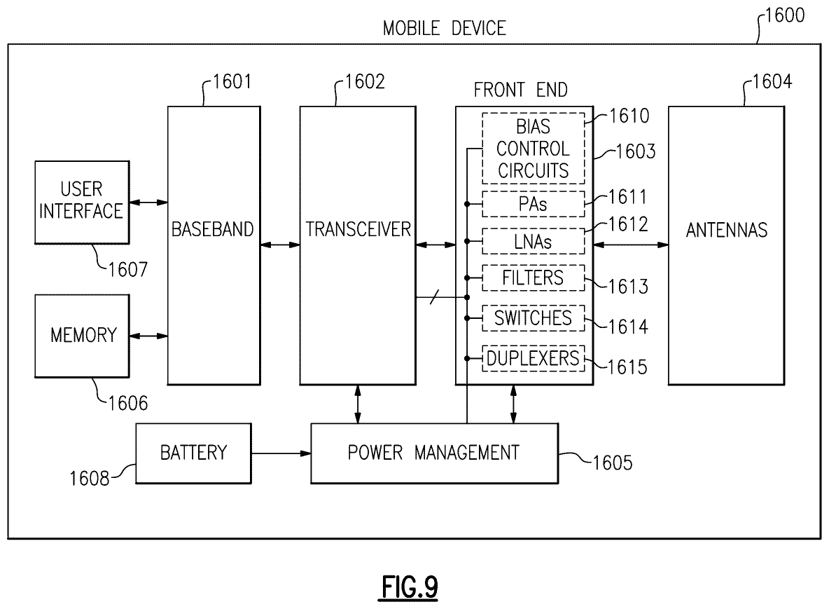

FIG. 8 is a schematic diagram of a module 800 that includes an active unbal converter circuit 801 implemented in accordance with one or more embodiments described herein and having one or more advantageous features described herein. The active unbal converter circuit 801 may be implemented as a single circuit or one or more separate converter circuits arranged to convert signals for the signal paths associated with a plurality of power amplifiers 802A and 802B. The module 800 also includes power amplifiers 802A and 802B, switches 804A and 804B, filters 806A and 806B, and an antenna switch 808. The module 800 is similar to that of FIG. 7, except that the module 800 includes an antenna switch 808 arranged to selectively couple a signal from the filters 806A and 806B to an antenna node. The filters 806A and 806B may correspond to the filters 706′ of FIG. 7.

FIG. 9 is a schematic diagram of one embodiment of a wireless device which in this example is a mobile device 1600. The mobile device 1600 includes a baseband system 1601, a transceiver 1602, a front end system 1603, antennas 1604, a power management system 1605, a memory 1606, a user interface 1607, and a battery 1608.

Although the mobile device 1600 illustrates one example of an RF system that can include one or more features of the present disclosure, the teachings herein are applicable to electronic systems implemented in a wide variety of ways.

The mobile device 1600 can be used for communication using a wide variety of communication technologies including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies, but may be particularly applicable to 5G technologies.

The transceiver 1602 generates RF signals for transmission and processes incoming RF signals received from the antennas 1604. It will be understood that various functionalities associated with the transmission and receiving of RF signals can be achieved by one or more components that are collectively represented in FIG. 9 as the transceiver 1602. In one example, separate components (for instance, separate circuits or dies) can be provided for handling certain types of RF signals.

As shown in in FIG. 9, the transceiver 1602 is connected to the front end system 1603 and to the power management circuit 1605 using a serial interface. All or part of the illustrated RF components can be controlled by the serial interface to configure the mobile device 1600 during initialization and/or while fully operational. In another embodiment, the baseband processor 1601 is additionally or alternative connected to the serial interface and operates to configure one or more RF components, such as components of the front end system 1603 and/or power management system 1605.

The front end system 1603 aids in conditioning signals transmitted to and/or received from the antennas 1604. In the illustrated embodiment, the front end system 1603 includes one or more bias control circuits 1610 for controlling power amplifier biasing, one or more power amplifiers 1611, one or more low noise amplifiers (LNAs) 1612, one or more filters 1613, one or more switches 1614, and one or more duplexers 1615. In addition, the front end system 1603 comprises an active unbal converter circuit implemented in accordance with one or more embodiments described herein and having one or more advantageous features described herein. In particular, the active unbal converter circuit is coupled at least to the one or more power amplifiers and is configured to convert a single-ended radio frequency input signal to a pair of differential output signals to be provided to one or more components of the front end system such as the one or more power amplifiers 1611. It will be appreciated that other implementations are possible.

For example, the front end system 1603 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1600 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 1604 can include antennas used for a wide variety of types of communications. For example, the antennas 1604 can include antennas for transmitting and/or receiving signals associated with a wide variety of frequencies and communications standards.

In certain implementations, the antennas 1604 support multiple-input and multiple-output (MIMO) communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1600 can operate with beamforming in certain implementations. For example, the front end system 1603 can include phase shifters having variable phase controlled by the transceiver 1602. Additionally, the phase shifters are controlled to provide beam formation and directivity for transmission and/or reception of signals using the antennas 1604. For example, in the context of signal transmission, the phases of the transmit signals provided to the antennas 1604 are controlled such that radiated signals from the antennas 1604 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1604 from a particular direction. In certain implementations, the antennas 1604 include one or more arrays of antenna elements to enhance beamforming.

The baseband system 1601 is coupled to the user interface 1607 to facilitate processing of various user input and output (I/O), such as voice and data. The baseband system 1601 provides the transceiver 1602 with digital representations of transmit signals, which the transceiver 1602 processes to generate RF signals for transmission. The baseband system 1601 also processes digital representations of received signals provided by the transceiver 1602. As shown in FIG. 16, the baseband system 1601 is coupled to the memory 1606 to facilitate operation of the mobile device 1600.

The memory 1606 can be used for a wide variety of purposes, such as storing data and/or instructions to facilitate the operation of the mobile device 1600 and/or to provide storage of user information.

The power management system 1605 provides a number of power management functions of the mobile device 1600. In certain implementations, the power management system 1605 includes a power amplifier (PA) supply control circuit that controls the supply voltages of the power amplifiers 1611. For example, the power management system 1605 can be configured to change the supply voltage(s) provided to one or more of the power amplifiers 1611 to improve efficiency, such as power added efficiency (PAE).

The power management system 1605 can operate in a selectable supply control mode, such an average power tracking (APT) mode or an envelope tracking (ET) mode. In the illustrated embodiment, the selected supply control mode of the power management system 1605 is controlled by the transceiver 1602. In certain implementations, the transceiver 1602 controls the selected supply control mode using the serial interface 1609.

As shown in FIG. 9, the power management system 1605 receives a battery voltage from the battery 1608. The battery 1608 can be any suitable battery for use in the mobile device 1600, including, for example, a lithium-ion battery. Although the power management system 1605 is illustrated as separate from the front end system 1603, in certain implementations all or part (for instance, a PA supply control circuit) of the power management system 1605 is integrated into the front end system 1603.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only, and the scope of the disclosure should be determined from proper construction of the appended claims, and their equivalents.

The teachings of the disclosure provided herein can be applied to other systems, not necessarily the system described above. The elements and acts of the various embodiments described above can be combined to provide further embodiments.

While some embodiments of the disclosure have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An active unbalanced-to-balanced converter circuit comprising:
a first output and a second output configured to output a pair of differential signals corresponding to a single-ended radio frequency input signal;
a current mirror circuit coupled to the input signal and including a first transistor and a second transistor;
a differential amplifier including a third transistor and a fourth transistor, the third transistor coupled between the first transistor and the first output and being configured to provide a first amplified output signal to the first output, and the fourth transistor coupled between the second transistor and the second output and being configured to provide a second amplified output signal to the second output; and
a bias circuit coupled to the third transistor and the fourth transistor and being configured to provide a bias voltage to the differential amplifier.

2. The active unbalanced-to-balanced converter circuit of claim 1 further including:
a first capacitor coupled between the third transistor and the fourth transistor;
a second capacitor coupled between the third transistor and a common ground, the second capacitor being configured to control an impedance at the third transistor; and
a third capacitor coupled between the fourth transistor and the common ground, the third capacitor being configured to control an impedance at the fourth transistor.

3. The active unbalanced-to-balanced converter circuit of claim 2 wherein a capacitance of the first capacitor is relatively large compared to the capacitance of the second capacitor and the third capacitor.

4. The active unbalanced-to-balanced converter circuit of claim 2 wherein the second capacitor is configured to control an impedance at an emitter of the third transistor, and the third capacitor is configured to control an impedance at an emitter of the fourth transistor.

5. The active unbalanced-to-balanced converter circuit of claim 2 wherein a capacitance of the second capacitor and the third capacitor are adjustable.

6. The active unbalanced-to-balanced converter circuit of claim 1 further comprising a first resistor coupled between an input of the active unbalanced-to-balanced converter circuit and the first transistor, and the input and the third transistor, the first resistor being configured to set an input impedance.

7. The active unbalanced-to-balanced converter circuit of claim 1 further comprising a first inductor coupled between the third transistor and the first output, and a second inductor coupled between the fourth transistor and the second output, the first inductor and the second inductor being coupled in symmetrical anti-phase.

8. The active unbalanced-to-balanced converter circuit of claim 1 further comprising a fourth capacitor and fifth capacitor coupled between the third transistor and the first output, and a sixth capacitor and a seventh capacitor coupled between the fourth transistor and the second output, the fourth and fifth capacitors being configured to provide impedance matching to the first amplified output signal and to block direct current at the first output, the sixth and seventh capacitors being configured to provide impedance matching to the second amplified output signal and to block direct current at the second output.

9. The active unbalanced-to-balanced converter circuit of claim 8 wherein the fourth, fifth, sixth, and seventh capacitors are tapped-capacitor impedance transformers.

10. The active unbalanced-to-balanced converter circuit of claim 1 further comprising a capacitor coupled to an input of the active unbalanced-to-balanced converter circuit and being configured to provide direct current blocking and a third inductor coupled between the input and the third transistor.

11. The active unbalanced-to-balanced converter circuit of claim 1 wherein the second amplified output signal has a phase difference of 180 degrees from the first amplified output signal.

12. The active unbalanced-to-balanced converter circuit of claim 1 wherein the bias circuit is coupled to the differential amplifier via a pair of resistors.

13. The active unbalanced-to-balanced converter circuit of claim 1 wherein the differential amplifier is a common-base amplifier, an emitter of the third transistor is coupled to a collector of the first transistor, a base of the third transistor is coupled to the bias circuit, and a collector of the third transistor is coupled to the first output.

14. The active unbalanced-to-balanced converter circuit of claim 13 wherein an emitter of the fourth transistor is coupled to a collector of the second transistor, a base of the fourth transistor is coupled to the bias circuit, and a collector of the fourth transistor is coupled to the second output.

15. The active unbalanced-to-balanced converter circuit of claim 1 wherein the differential amplifier is a common-gate amplifier, a source of the third transistor is coupled to a drain of the first transistor, a gate of the third transistor is coupled to the bias circuit, a drain of the third transistor is coupled to the first output, a source of the fourth transistor is coupled to a drain of the second transistor, a gate of the fourth transistor is coupled to the bias circuit, and a drain of the fourth transistor is coupled to the second output.

16. The active unbalanced-to-balanced converter circuit of claim 1 wherein the bias circuit is coupled to the first transistor and the second transistor and is configured to provide a current mirror bias voltage to the current mirror circuit.

17. The active unbalanced-to-balanced converter circuit of claim 1 wherein the first transistor, second transistor, third transistor, and fourth transistor are N-channel transistors.

18. The active unbalanced-to-balanced converter circuit of claim 1 wherein the bias circuit includes a reference current, the bias circuit being configured to increase the reference current by a factor of N where N is a ratio of an operating current of the first transistor and the second transistor compared with the reference current in the bias circuit.

19. A radio frequency module comprising:
an active unbalanced-to-balanced converter circuit including: a first output and a second output configured to output a pair of differential signals corresponding to a single-ended radio frequency input signal; a current mirror circuit coupled to an input signal and including a first transistor and a second transistor; a differential amplifier including a third transistor and a fourth transistor, the third transistor coupled between the first transistor and the first output and being configured to provide a first amplified output signal to the first output, and the fourth transistor coupled between the second transistor and the second output and being configured to provide a second amplified output signal to the second output; and a bias circuit coupled to the third transistor and the fourth transistor and being configured to provide a bias voltage to the differential amplifier; and
one or more power amplifiers coupled to the active unbalanced-to-balanced converter circuit.

20. A wireless communication device comprising a radio frequency module implemented on a die, the radio frequency module including:
an active unbalanced-to-balanced converter circuit including: a first output and a second output configured to output a pair of differential signals corresponding to a single-ended radio frequency input signal; a current mirror circuit coupled to the input signal and including a first transistor and a second transistor; a differential amplifier including a third transistor and a fourth transistor, the third transistor coupled between the first transistor and the first output and being configured to provide a first amplified output signal to the first output, and the fourth transistor coupled between the second transistor and the second output and being configured to provide a second amplified output signal to the second output; a bias circuit coupled to the third transistor and the fourth transistor and being configured to provide a bias voltage to the differential amplifier;
one or more power amplifiers coupled to the active unbalanced-to-balanced converter circuit; and
one or more radio frequency antennas.
